(19) United States
(12) Patent Application Publication
(10) Pub. No.: US 2026/0088784 A1
(43) Pub. Date: Mar. 26, 2026

(54) COMMON-MODE STABILIZATION OF HIGH-FREQUENCY DIFFERENTIAL DISTRIBUTED DRIVER AMPLIFIER

(71) Applicant: CIENA CORPORATION, Hanover, MD (US)

(72) Inventors: Jeffrey Henry Bennett, Ottawa (CA); Aref Pourzadi, Ottawa (CA)

(73) Assignee: CIENA CORPORATION, Hanover, MD (US)

(21) Appl. No.: 18/895,659

(22) Filed: Sep. 25, 2024

(51) Int. Cl. H03F 3/343; H03F 3/45; H03F 3/60

(52) U.S. Cl. CPC H03F 3/3435; H03F 3/45085; H03F 3/60; H03F 2203/45024

(57) ABSTRACT

Aspects of the subject disclosure may include, for example, a common emitter stage having a differential input configured to receive an input signal from an input transmission line, a common base stage coupled with the common emitter stage and having a differential output configured to provide a differential output signal to an output transmission line, and a biasing network to bias the common base stage, the biasing network including components selected to limit common mode gain of the common base stage at relatively high frequencies of interest without affecting a differential mode gain of the common base stage. Other embodiments are disclosed.

### FIELD OF THE DISCLOSURE

The subject disclosure relates to techniques for design and operation of amplifier circuits.

### BACKGROUND

High performance optical modulator circuits require high performance amplifier circuits to drive the optical modulators. Such amplifier circuits should be stable in both differential mode and common mode and provide a large bandwidth.

### BRIEF DESCRIPTION OF THE DRAWINGS

Reference will now be made to the accompanying drawings, which are not necessarily drawn to scale, and wherein:

FIG. 1 is a block diagram illustrating an exemplary, non-limiting embodiment of an optical transmission unit in accordance with various aspects described herein.

FIG. 2 is a block diagram illustrating an exemplary, non-limiting embodiment of an amplifier in accordance with various aspects described herein.

FIG. 3 is a block diagram illustrating a first exemplary, non-limiting embodiment of an amplifier gain stage in accordance with various aspects described herein.

FIG. 4 is a block diagram illustrating a second exemplary, non-limiting embodiment of an amplifier gain stage in accordance with various aspects described herein.

FIG. 5 is a block diagram illustrating a third exemplary, non-limiting embodiment of an amplifier gain stage in accordance with various aspects described herein.

### DETAILED DESCRIPTION

The subject disclosure describes, among other things, illustrative embodiments for an amplifier gain stage with improved stability in both differential mode and common mode operation. At sufficiently high frequency in integrated circuits, parasitic capacitances become a major factor limiting the circuit impedances that can be used. All circuit interconnections are effectively transmission lines with characteristic impedances less than 377 Ohms, i.e., the impedance of free space. Conventional methods of limiting common mode gain are power hungry and ineffective at high frequency because of parasitic and device capacitance. The poor high frequency performance leads to common mode instability.

In accordance with features of embodiments described herein, In this manner, a common mode cascode matching circuit is improved to reduce high frequency gain without affecting differential mode gain. Further, a feedforward common mode signal is applied to the cascode stage to further improve common mode operation. Other embodiments are described in the subject disclosure.

One or more aspects of the subject disclosure include an amplifier circuit including a common emitter stage having a differential input configured to receive an input signal from an input transmission line, a common base stage coupled with the common emitter stage and having a differential output configured to provide a differential output signal to an output transmission line, and a biasing network to bias the common base stage, the biasing network including components selected to limit common mode gain of the common base stage at relatively high frequencies of interest without affecting a differential mode gain of the common base stage.

One or more aspects of the subject disclosure include a distributed differential amplifier which may include a plurality of gain stages, a gain stage of the plurality of gain stages comprising a cascode amplifier configured to receive a differential input signal at a differential input and to provide a differential output signal at a differential output, and a biasing network, the biasing network including components selected to limit common mode gain of the gain stage at relatively high operating frequencies of interest for the differential input signal without affecting a differential mode gain of the gain stage.

One or more aspects of the subject disclosure include a plurality of gain stages, a gain stage of the plurality of gain stages comprising a first amplifier stage having a differential input configured to receive a differential input signal from an input transmission line, wherein the differential input signal comprises common mode signals and differential mode signals across a band of operating frequencies, a second amplifier stage coupled to the first amplifier stage and having a differential output configured to provide a differential output signal to an output transmission line, the first amplifier stage and the second amplifier stage cooperating to provide a common mode gain for the common mode signals and a differential mode gain for the differential mode signals, and a biasing circuit coupled to the second amplifier stage, the biasing circuit including a resistive element coupled between a common node of the second amplifier stage and an alternating current (AC) ground, the resistive element selected to limit the common mode gain at relatively high frequencies of the band of operating frequencies without affecting the differential mode gain.

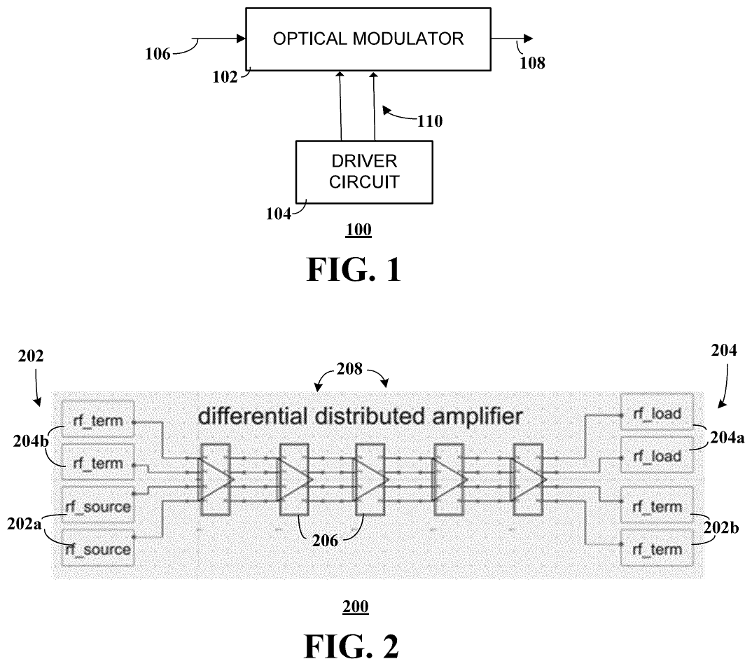

FIG. 1 is a block diagram illustrating an exemplary, non-limiting embodiment of an optical transmission unit 100 in accordance with various aspects described herein. In the illustrated embodiment, the optical transmission unit 100 includes an optical modulator 102 and a driver circuit 104. The optical modulator 102 receives an input light signal at an input 106. The optical modulator 102 modulates the input light signal to produce an output signal at an output 108. Modulation is according to a modulation signal 110 received from the driver circuit 104. In embodiments, the optical modulator may be of the Mach-Zehnder (MZ) type or any other suitable modulation device.

Long distance optical communications use light beams conveyed through optical fibers to transmit data and other information. Optical communications permits data rates up to 1.6 Tbps and beyond. Each end of the optical fiber requires a modulator or demodulator for conversion between electronic data and optical data. Thus, a key part of an optical transmission system is a modulation scheme to put the data onto a light beam. Such modulation is conventionally performed by an optical modulator that is driven by a driver circuit, as in the optical transmission unit 100.

A suitable driver circuit may require a flat frequency response from near DC up to several hundred gigahertz. A suitable driver circuit must also generate a substantial amount of power to drive the current optical modulator technology. Moreover, current generation optical modulators employ differential drive so the driver circuit generally must provide differential drive as well. Differential drive reduces the required amount of output voltage swing or peak-to-peak output voltage. However, the differential drive for a driver circuit may require a bandwidth greater than 100 GHz and output voltage greater than 4 volts peak to peak.

Driver circuits are manufactured in integrated circuits using conventional semiconductor manufacturing technology. Previous generations used silicon technology because the technology is well-developed and well-understood. However, silicon circuits generally have a breakdown voltage too small to support 4 volt peak to peak signals. Accordingly, a suitable driver circuit may require a switch to an alternative semiconductor technology. One example is indium phosphide (InP). Circuits of indium phosphide generally have a good combination of high frequency performance and breakdown voltages.

FIG. 2 is a block diagram illustrating an exemplary, non-limiting embodiment of an amplifier 200 in accordance with various aspects described herein. In the illustrated embodiment, the amplifier 200 is a differential distributed amplifier. The amplifier 200 may be used in a very high-performance circuit for amplifying electrical signals. In exemplary embodiments, the amplifier 200 may have a bandwidth of 100 GHz or more and an output voltage swing of 4 V peak to peak.

The amplifier 200 includes an input 202, an output 204 and a plurality of stages 206. A distributed amplifier such as amplifier 200 is a type of electronic amplifier that uses transmission lines to distribute the input signal across multiple amplifier stages. This design approach allows for a wider bandwidth and higher gain compared to traditional amplifiers. In the exemplary embodiment, the amplifier 200 is formed in a single integrated circuit of a suitable semiconductor material such as indium phosphide.

The input signal is received at the input 202, divided and fed into the plurality of stages 206. In the illustrated example, the amplifier 200 includes five stages. In other embodiments, any suitable number may be used. The plurality stages 206 are connected in parallel. Transmission lines 208 are used to connect the input and output stages. The transmission lines 208 may be in transmission line segments coupling respective inputs or outputs. These lines act as delay lines, ensuring that the signals arrive at each stage at the correct time. Each respective amplifier stage amplifies the portion of the signal it receives. The amplified signals are then combined at the output 204, resulting in a significantly amplified version of the original input signal received at the input 202. Amplification among the multiple stages is additive.

Distributed amplifiers such as the amplifier 200 are able to operate over a wide frequency range, including 100 GHz and beyond. By combining the amplification from the plurality of stages 206, the amplifier can achieve high gain, including a gain adequate for use in a driver circuit for an optical amplifier. A distributed amplifier such as amplifier 200 can exhibit reduced parasitic effects. For example, to provide the output power required generally requires using larger devices to handle the power. However, the larger devices introduce larger parasitic capacitances, resistance and inductances. The use of transmission lines can help to minimize parasitic effects. The transmission lines have distributed inductance and capacitance. The input capacitance in the devices is effectively cancelled using excess inductance in the input transmission line. Similarly, the output capacitance is cancelled by the inductance on the output transmission line.

In FIG. 2, the input 202 includes a differential radio frequency (RF) source 202a and a differential RF terminator 202b. Similarly, the output 204 includes a differential RF load 204a and a differential RF terminator 204b. The respective terminations and loads provide proper termination for the transmission lines 208, for example, to eliminate destructive reflections on the transmission lines 208. The differential RF load 204a may include or be coupled to the differential input of an optical modulator. In design, the transmission delay between the stages is properly the same on the input side and the output side so that the outputs add up properly without a phase shift.

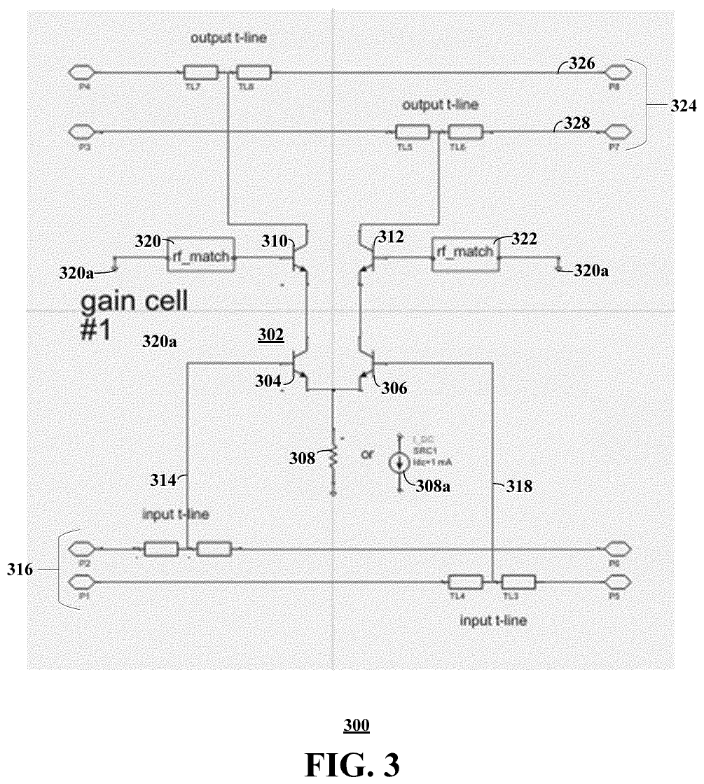

FIG. 3 is a block diagram illustrating an exemplary, non-limiting embodiment of an amplifier gain stage 300 in accordance with various aspects described herein. The gain stage 300 may be used in conjunction with the amplifier 200 of FIG. 2, incorporating gain stage 300 into each of the plurality of stages 206 in the amplifier 200.

The gain stage 300 is configured as a differential amplifier 302. The differential amplifier 302 includes two common emitter connected transistors including a first transistor 304 and a second transistor 306, and a tail resistor 308. The tail resistor 308 is commonly coupled to the emitters of the first transistor 304 and the second transistor 306 to provide a biasing current. The common emitter transistors feed into a pair of common base transistors including transistor 310 and transistor 312. The emitter of transistor 310 is coupled to the collector of transistor 304. The emitter of transistor 312 is coupled to the collector of transistor 306.

This configuration is referred to as a cascode. In this configuration, the upper common base stage including transistor 310 and transistor 312 provides a low impedance for the lower stage including first transistor 304 and second transistor 306 so that the voltages generated on the nodes connecting upper stage and the lower stage are minimized. For the lower stage transistors, first transistor 304 and second transistor 306, their performance is limited by the collector-base capacitance, which is a feedback capacitance. The cascode may provide the best performance from an amplifier stage.

The first transistor 304 receives at its base a first input signal 314 from an input transmission line 316. Similarly, the second transistor 306 receives at its base a second input signal 318 from the input transmission line 316. The first input signal 314 and the second input signal 318 form a differential input signal. The differential amplifier 302 is differential or dual ended in nature. The collectors of the cascode stage provide the differential output signal 324 including a first output signal 326 and a second output signal 328.

High performance (e.g., with a bandwidth greater than 50 GHz and output voltage greater than 3Vptp) bipolar distributed differential amplifiers used with optical modulators in fiber-optic data transmission systems need to be stable in both differential mode and common mode. In differential mode, two input alternating current (AC) signals swing out of phase with each other; in common mode, the two input AC signals swing together, in phase. In order to generate large bandwidth, a cascode-pair gain stage is commonly used, with common-mode gain limited by using a tail resistor such as resistor 308 or a current source, as illustrated in FIG. 3. Common mode stability requires that gain be limited, particularly at high frequencies which can be problematic with this configuration.

In general, any real signal received at the input of the gain stage 300 will have some distortion on it, which is equivalent to a mixture of a common mode signal and a differential mode signal. Similarly, any imbalance on the output signal can also give the effect of a common mode signal and a differential mode signal. Therefore, the design of the amplifier requires that both the common mode and the differential mode be stable. For example, inclusion of the resistor 308 reduces gain for a common mode signal while not affecting the differential mode signal. In exemplary embodiments, a voltage of approximately 400 mV is maintained across the tail resistor 308. The tail resistor 308 further provides stability for the differential amplifier 302 against thermal runaway. As illustrated in FIG. 3, in some embodiments, a high impedance current source 308a may be substituted for the resistor 308 to further increase the common mode rejection ratio.

Controlling impedance at the bases of the cascode transistors, transistor 310 and transistor 312, is important for amplifier stability. The cascode amplifier is relatively sensitive to the impedance at the bases of the cascode transistors. In general, if the impedance at one or both base nodes is inductive or too low, the output impedance of the cascode stage can go negative, including at a high frequency input. When the output impedance goes negative, the amplifier gain stage 300 becomes unstable. It is thus desirable to limit the common mode gain specifically at high frequencies without affecting the differential mode gain, thereby enhancing stability, but with little additional power.

As noted, in a cascode amplifier stage such as is illustrated in FIG. 3, the termination impedance of the upper base transistor is critical to the high frequency gain and amplifier stability. In the differential version illustrated in FIG. 3, two different matching impedances can be used for the common mode and the differential mode. This may ensure faster roll-off for the common mode gain than the differential mode and thus greater stability.

In the example of FIG. 3, matching RF circuits form a low impedance to AC ground. A match circuit 320 couples the base of the transistor 310 to AC ground 320A. Similarly, a match circuit 322 couples the base of the transistor 312 to AC ground 320a. Rejection of common mode signals requires a very good connection to ground, which may be difficult to obtain in an integrated circuit. For example, if the circuit is connected to AC ground through a bonding wire to a package containing the circuit, an inductance is introduced between the base and ground. Thus, difficulty getting a high frequency ground may result in common mode instability.

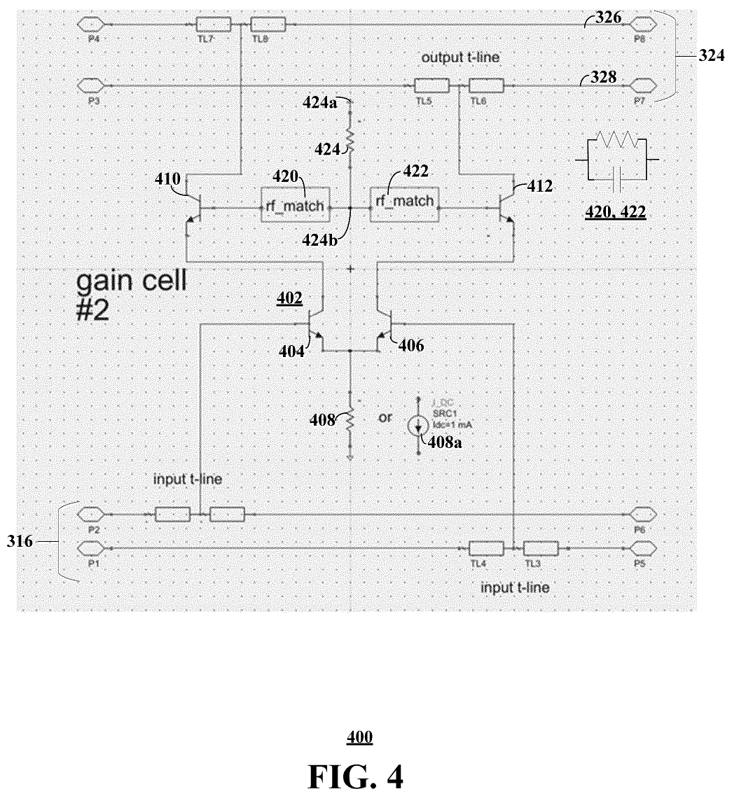

FIG. 4 is a block diagram illustrating an exemplary, non-limiting embodiment of an amplifier gain stage 400 in accordance with various aspects described herein. The gain stage 400 may be used in conjunction with the amplifier 200 of FIG. 2, incorporating gain stage 400 into each of the plurality of stages 206 in the amplifier 200. The gain stage 400 may be termed a differential cascode amplifier. In embodiments, the gain stage is formed in an integrated circuit using any suitable semiconductor technology such as silicon or indium phosphide.

The gain stage 400 is configured as a differential amplifier 402. The differential amplifier 402 includes two common emitter connected transistors including a first transistor 404 and a second transistor 406, and a tail resistor 408. The base of the first transistor 404 and the base of the second transistor 406 form the differential input to the differential amplifier 402 and the gain stage 400, and are coupled to the input transmission line 316. The tail resistor 408 is commonly coupled to the emitters of the first transistor 404 and the second transistor 406 to provide a biasing current. In some embodiments, the tail resistor 408 may be replaced with a current mirror current source such as current source 408a. The tail resistor 408 or current source 408a provide functions and benefits similar to those of the tail resistor 308 in FIG. 3.

In the cascode stage, the common emitter transistors feed into a pair of common base transistors including transistor 410 and transistor 412. The emitter of transistor 410 is coupled to the collector of transistor 404. The emitter of transistor 412 is coupled to the collector of transistor 406. The base of transistor 410 is coupled through an RF match circuit 420 to a node designated common node 424b in FIG. 4, through a resistor 424 to virtual ground or AC ground at a suitable voltage supply 424a. Similarly, the base of transistor 412 is coupled through an RF match circuit 422 to the common node 424b with the resistor 424 and then to virtual ground or AC ground at a suitable voltage supply 424a. The resistor 424 may have any suitable value, such as 50 Ohms, and may be selected to limit the common mode gain of the common base stage, specifically at high frequencies such as above 50 GHz, without affecting the differential mode gain at high frequencies. This eliminates a possibility of an output impedance of the common base stage passing through zero and going negative at high frequencies of interest. With the resistor or another load network in place between the common node 424b and virtual ground associated with 424a, the common mode gain experiences faster roll off with increasing frequency than does the differential mode and thus the common base stage, and the gain stage 400, experiences greater stability, especially at higher frequences. In the example embodiments, higher frequencies refers to operating frequencies of the input signal above 50 GHz and, in further embodiments, above 100 GHz.

Similar to the cascode configuration of FIG. 3, the upper common base stage including transistor 410 and transistor 412 provides a low impedance for the lower stage including first transistor 404 and second transistor 406 so that the voltages generated on the nodes connecting upper stage and the lower stage are minimized. In the differential version of the cascode stage shown in FIG. 4, two different matching impedances, RF match circuit 420 and RF match circuit 422, can be used for the common mode and the differential mode.

Any suitable RF matching circuit may be employed for the RF match circuit 420 and the RF match circuit 422, such as a parallel resistor and capacitor combination as shown for one embodiment in FIG. 4. In an exemplary embodiment, the RF match circuit 420 and the RF match circuit 422 may include a 15 Ohm resistor and a 20 fF parallel capacitance. This may ensure faster roll off for the common mode gain than the differential mode and thus greater stability. This requires only a small increase in power to sink the base current from the voltage supply 424a through the resistor 424.

The RF match circuit 420 and the RF match circuit 422 operates as a bias circuit for the common base stage of the cascode to limit common mode gain of the common base stage at relatively high frequencies (i.e., frequencies greater than 5 GHz) without affecting differential mode gain. If the base of transistor 410 and the base of transistor 412 were each tied to AC ground (such as through a DC power supply voltage source), the output impedance would increase with operating frequency. At high frequency, such as greater than 50 GHz, the output impedance would go negative. This would create unstable operation for the gain stage 400. Inserting a series resistance such as resistor 424 between the common node 424b, between the base of transistor 410 and the base of transistor 412, and the DC power supply and AC ground, operates to prevent negative impedance. At low frequency, the transistor 410 and the transistor 412 operate as if the base is grounded at AC ground. At higher frequencies, the transistor 410 and the transistor 412 see base-emitter capacitance. Adding a resistor-capacitor pair as the RF match circuit 420 and the RF match circuit 422 produces a voltage divider between the base-emitter capacitance and the capacitance included in the RF match circuit 420 and the RF match circuit 422.

Similar to the gain stage 300 of FIG. 3, the collectors of the cascode stage, including transistor 410 and transistor 412, provide the differential output signal 324 including a first output signal 326 and a second output signal 328 on a pair of transmission lines.

Thus, in the gain stage 400, the T-connection at the base of transistor 410 and the base of transistor 412 and the resistor 424 operates to greatly reduce common mode gain for the gain stage 400. That in turn operates to improve stability for the gain stage 400. However, implementations using indium phosphide may be limited by the gain of the transistors. Exemplary bipolar transistors fabricated using InP may have a typical β of 30. In contrast, conventional silicon bipolar transistors may have a typical β of 1000. Thus, with a silicon transistor using a modest input current yields a very high input impedance from the transmission line 316.

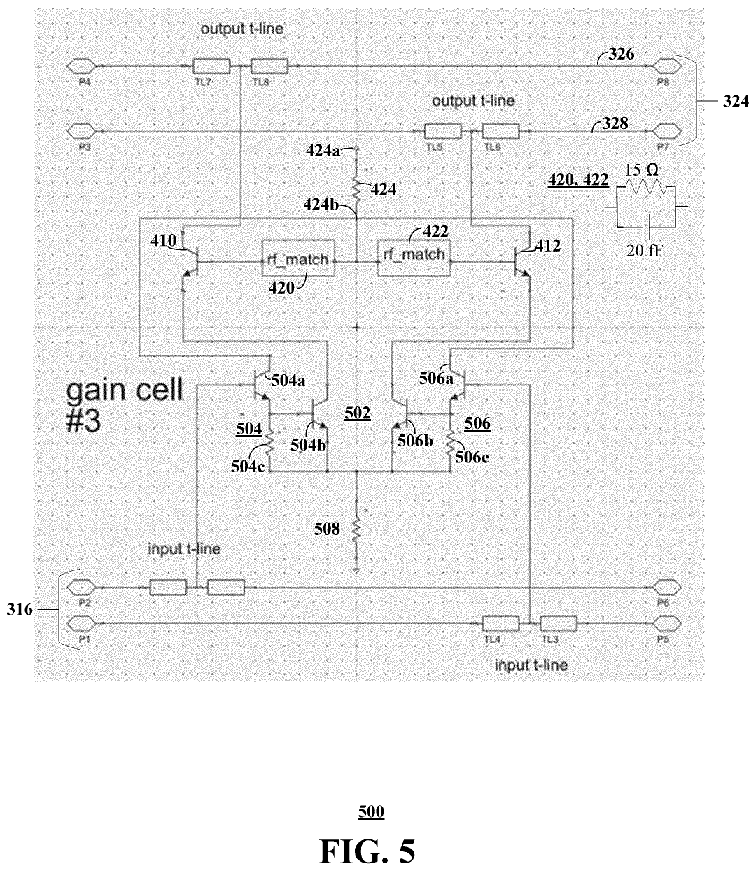

FIG. 5 is a block diagram illustrating a further exemplary, non-limiting embodiment of an amplifier gain stage 500 in accordance with various aspects described herein. The gain stage 500 may be used in conjunction with the amplifier 200 of FIG. 2, incorporating gain stage 500 into each of the plurality of stages 206 in the amplifier 200. The gain stage 500 may be termed a differential cascode amplifier. The gain stage 500 may provide improved input impedance relative to the gain stage 400 of FIG. 4.

The gain stage 500 is configured as a differential amplifier 502. Relative to the differential amplifier 402 of FIG. 4, the differential amplifier 502 includes two Darlington pair transistors including a first Darlington pair 504 and a second Darlington pair 506. The first Darlington pair 504 includes a transistor 504a forming an input transistor and a transistor 504b forming a switching transistor, along with a resistor 504c coupled between the transistor emitters. The second Darlington pair 506 includes a transistor 506a forming an input transistor and a transistor 506b forming a switching transistor, along with a resistor 506c coupled between the transistor emitters. A tail resistor 508 provides biasing current and may be replaced with a current mirror current source if appropriate or desired.

The first Darlington pair 504 and a second Darlington pair 506 are coupled to the input transmission line 316 and provide improved input impedance for the gain stage 500.

The cascode stage of the gain stage 500 is similar to the cascode stage of the gain stage 400 in FIG. 4. In the gain stage 500, the Darling transistor pairs feed into a pair of common base transistors including transistor 410 and transistor 412. The emitter of transistor 410 is coupled to the collector of transistor 504b in the first Darlington pair 504. The emitter of transistor 412 is coupled to the collector of transistor 506b in the second Darlington pair 506. The base of transistor 410 is coupled through an RF match circuit 420 and a resistor 424 to virtual ground or AC ground at a suitable voltage supply 424a. Similarly, the base of transistor 412 is coupled through an RF match circuit 422 to the resistor 424 and then to virtual ground or AC ground at a suitable voltage supply 424a. Any suitable RF matching circuit may be employed for the RF match circuit 420 and the RF match circuit 422, such as a parallel resistor and capacitor combination as shown for an exemplary embodiment in FIG. 5. In an exemplary embodiment, the RF match circuit 420 and the RF match circuit 422 may include a 15 Ohm resistor and a 20 fF parallel capacitance.

The parallel R-C combination of the RF match circuit 420 and the RF match circuit 422 generally operate on the same principles described for the similar circuit of FIG. 4. For example, in common mode operation, a common signal is received at the input transmission line 316 and applied to the base of the transistor 504a in the Darlington pair 504 and to the base of the transistor 506a in the Darlington pair 506. Thus, the voltages at both inputs of the differential amplifier 502 are rising and falling together with the voltage of the common signal. When both voltages rise together, the current in the emitter follower transistors, transistor 504a and transistor 506a, increases. Those currents flow through the resistor 424. As a result, a voltage drop is produced across the resistor 424, lowering the voltage at the common node 424b. Further, the emitters of the cascode transistors, transistor 410 and transistor 412, come down in voltage as well. Thus, the circuit of FIG. 5 compensates for the increase that would be seen on the base-emitter voltages of the cascode transistors 410, 412 during common mode operation (due to the rise in voltage at the Darlington pairs) by bringing down the voltage on the common node 424b. The collectors of the input transistors 504a, 506a of the Darlington pairs 504, 506 thus provide an inverted common-mode signal to the bases of the upper transistors, transistor 410 and transistor 412 of the cascode stage. This serves to further reduce the common mode gain and to improve stability.

Any suitable adjustments may be made to the RF match circuit 420 and the RF match circuit 422 to improve or optimize performance of the gain stage or to meet any suitable design goals.

Similar to the cascode configuration of FIG. 4, the upper common base stage including transistor 410 and transistor 412 in gain stage 500 of FIG. 5 provides a low impedance for the lower stage including first transistor 404 and second transistor 406 so that the voltages generated on the nodes connecting upper stage and the lower stage are minimized.

Similar to the gain stage 400 of FIG. 4, the collectors of the cascode stage, including transistor 410 and transistor 412, provide the differential output signal 324 including a first output signal 326 and a second output signal 328 on a pair of transmission lines.

The collectors of the first Darlington stages may be tied to any suitable connection. In the embodiment of FIG. 5, the collector of transistor 504a and the collector of transistor 506a are each coupled directly to the node that is common with the RF match circuit 420, the RF match circuit 422 and the resistor 424. That connection has a beneficial effect of reducing common mode gain for the gain stage and is particularly applicable given low-gain transistors available in indium phosphide technology. The illustrated connection has a beneficial negative affect on the common mode response of the cascode amplifier, while not significantly affecting differential mode performance.

With the common mode termination impedance in place as illustrated in FIG. 5, it can be used as a load resistor to feed an inverted common-mode signal to the bases of the upper transistors, including transistor 410 and transistor 412. This further reduces the common mode gain. The inverted common mode signal is conveniently available from the first stage of Darlington pair used to replace the bottom transistor of the cascode, transistor 504a and transistor 504b.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

As may also be used herein, the term(s) “operably coupled to”, “coupled to”, and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. An amplifier circuit, comprising:
a common emitter stage having a differential input configured to receive an input signal from an input transmission line;
a common base stage coupled with the common emitter stage and having a differential output configured to provide a differential output signal to an output transmission line; and
a biasing network to bias the common base stage, the biasing network comprising a resistive element coupled between a common node of the common base stage and a ground node.

2. The amplifier circuit of claim 1, wherein the common base stage comprises:
a first common base transistor having an emitter coupled to the common emitter stage, a collector coupled to the differential output, and a base coupled to the common node with the resistive element; and
a second common base transistor having an emitter coupled to the common emitter stage, a collector coupled to the differential output, and a base coupled to the common node with the resistive element and the base of the first common base transistor.

3. The amplifier circuit of claim 2, wherein the biasing network comprises:
a first radio frequency matching network coupled between the base of the first common base transistor and the common node; and
a second radio frequency matching network coupled between the base of the second common base transistor and the common node.

4. The amplifier circuit of claim 3, wherein:
the first radio frequency matching network comprises a first resistor and a first parallel-connected capacitor between the base of the first common base transistor and the common node; and
the second radio frequency matching network comprises a second resistor and a second parallel-connected capacitor between the base of the first common base transistor and the common node.

5. The amplifier circuit of claim 1, wherein the biasing network comprises:
a resistive element selected to limit common mode gain of the common base stage at relatively high frequencies of interest without affecting a differential mode gain of the common base stage.

6. The amplifier circuit of claim 1, wherein the common emitter stage comprises:
a first Darlington-connected pair of transistors coupled to the input transmission line to receive a first signal of the input signal;
a second Darlington-connected pair of transistors coupled to the input transmission line to receive a second signal of the input signal; and
a biasing resistor coupled to emitters of the first Darlington-connected pair of transistors and the second Darlington-connected pair of transistors to provide a biasing current.

7. The amplifier circuit of claim 6, wherein:
the first Darlington-connected pair of transistors comprises an input transistor having a collector coupled to the common node of the common base stage; and
the second Darlington-connected pair of transistors comprises an input transistor having a collector coupled to the common node of the common base stage.

8. The amplifier circuit of claim 7, wherein the biasing network comprises:
a first radio frequency matching network coupled between a base of a first common base transistor of the common base stage and the common node; and
a second radio frequency matching network coupled between a base of a second common base transistor and a common node.

9. The amplifier circuit of claim 8, wherein:
the first Darlington-connected pair of transistors and the second Darlington-connected pair of transistors provide an inverted common-mode signal to the base of a first common base transistor and the base of a second common base transistor to reduce common mode gain of the common base stage at relatively high frequencies of interest.

10. The amplifier circuit of claim 9, wherein:
the first Darlington-connected pair of transistors and the second Darlington-connected pair of transistors provide an inverted common-mode signal to reduce common mode gain of the common emitter stage without affecting differential mode gain of the common emitter stage.

11. A distributed differential amplifier, comprising:
a plurality of gain stages, a gain stage of the plurality of gain stages comprising:
a cascode amplifier configured to receive a differential input signal at a differential input and to provide a differential output signal at a differential output; and
a biasing network, the biasing network including a resistive element coupled between a common node of the cascode amplifier and a ground node to improve stability of the gain stage at relatively high frequencies of operation.

12. The distributed differential amplifier of claim 11, wherein the cascode amplifier comprises:
a common emitter stage; and
a common base stage;
wherein the biasing network comprises a termination impedance coupled between the ground node and the common node, the termination impedance selected to provide a faster roll off in a common mode gain versus frequency at relatively high operating frequencies of interest than a roll off in a differential mode and thus increase stability of the gain stage.

13. The distributed differential amplifier of claim 12, wherein the common base stage comprises:
a first common base stage having an emitter coupled to the common emitter stage of the gain stage, a collector coupled to the differential output, and a base coupled to the biasing network; and
a second common base stage having an emitter coupled to the common emitter stage of the gain stage, a collector coupled to the differential output, and a base coupled to the biasing network.

14. The distributed differential amplifier of claim 11, wherein the gain stage comprises:
a voltage amplification stage configured to receive the differential input signal, the voltage amplification stage comprising:
a first Darlington-connected pair of transistors coupled to an input transmission line to receive a first signal of the differential input signal, the first Darlington-connected pair of transistors comprising a collector coupled to the common node of the biasing network; and
a second Darlington-connected pair of transistors coupled to the input transmission line to receive a second signal of the differential input signal, the second Darlington-connected pair of transistors comprising a collector coupled to the common node of the biasing network.

15. The distributed differential amplifier of claim 14, wherein the first Darlington-connected pair of transistors and the second Darlington-connected pair of transistors provide an inverted common-mode signal to the common node to reduce a common mode gain of the gain stage at relatively high operating frequencies of interest.

16. A distributed amplifier circuit, comprising:
a plurality of gain stages, a gain stage of the plurality of gain stages comprising:
a first amplifier stage having a differential input configured to receive a differential input signal from an input transmission line, wherein the differential input signal comprises common mode signals and differential mode signals across a band of operating frequencies;
a second amplifier stage coupled to the first amplifier stage and having a differential output configured to provide a differential output signal to an output transmission line, the first amplifier stage and the second amplifier stage cooperating to provide a common mode gain for the common mode signals and a differential mode gain for the differential mode signals; and
a biasing circuit coupled to the second amplifier stage, the biasing circuit including a resistive element coupled between a common node of the second amplifier stage and ground, the resistive element selected to limit the common mode gain at relatively high frequencies of the band of operating frequencies without affecting the differential mode gain.

17. The distributed amplifier circuit of claim 16, wherein the relatively high frequencies of the band of operating frequencies comprise frequencies above 50 GHz.

18. The distributed amplifier circuit of claim 16, wherein the first amplifier stage comprises:
a first Darlington-connected pair of transistors coupled to the input transmission line to receive a first signal of the differential input signal; and
a second Darlington-connected pair of transistors coupled to the input transmission line to receive a second signal of the differential input signal;
wherein the first Darlington-connected pair of transistors and the second Darlington-connected pair of transistors comprise collectors coupled to the common node of the second amplifier stage to limit the common mode gain at the relatively high frequencies of the band of operating frequencies without affecting the differential mode gain, and wherein the first Darlington-connected pair of transistors and the second Darlington-connected pair of transistors provide an inverted common-mode signal to the common node of the second amplifier stage to reduce the common mode gain at the relatively high frequencies of the band of operating frequencies.

19. The distributed amplifier circuit of claim 18, wherein the second amplifier stage comprises:
a first common base transistor having an emitter coupled to the first amplifier stage, a collector coupled to the differential output, and a base coupled to the common node with the resistive element; and
a second common base transistor having an emitter coupled to the first amplifier stage, a collector coupled to the differential output, and a base coupled to the common node with the resistive element and the base of the first common base transistor.

20. The distributed amplifier circuit of claim 19, wherein the biasing circuit comprises:
a first radio frequency matching network coupled between the base of the first common base transistor and the common node; and
a second radio frequency matching network coupled between the base of the second common base transistor and the common node.
